(19) United States
(12) Patent Application Publication
(10) Pub. No.: US 2011/0113312 A1
(43) Pub. Date: May 12, 2011

(54) CHECK MATRIX GENERATING METHOD, CHECK MATRIX, DECODING APPARATUS, AND DECODING METHOD

(76) Inventors: Hideki Kobayashi, Saitama (JP); Takuya Shiroto, Yokohama (JP)

(21) Appl. No.: 12/996,682

(22) PCT Filed: Jun. 9, 2008
(86) PCT No.: PCT/JP2008/060546

§ 371 Date: Dec. 27, 2010

(51) Int. Cl. H03M 13/03; G06F 11/00

(52) U.S. Cl. 714/801; 714/E11.001

(57) ABSTRACT

A check matrix generating method of generating a check matrix (H) for decoding coded modulation data, which is encoded by a low-density parity check code and which is modulated by converting a-bit data (wherein a is a natural number) to b-bit data (wherein b is a natural number) wherein a is a modulation symbol unit, the method provided with: a check matrix generating process of generating the check matrix by determining each element such that the number of elements of 1 is less than or equal to one, out of a elements corresponding to data of the same modulation symbol in each of rows which constitute the check matrix.

### TECHNICAL FIELD

The present invention relates to a method of generating a check matrix for decoding data encoded by a LDPC (Low Density Parity Check) code, a check matrix generated by the method of generating the check matrix, a decoding apparatus and a decoding method which use the check matrix.

### BACKGROUND ART

The LDPC code is an error correction code defined by a sparse check matrix in which the number of elements “1” is extremely small with respect to the number of elements “0”. The LDPC code has such a characteristic that there is a difference in error correction capability for each code word bit after coding, depending on the number of elements “1 in each column in the check matrix (i.e. column weight).

For the decoding of the data encoded by the LDPC code, the aforementioned check matrix is used (e.g. refer to a patent document 1). Moreover, in order to improve the error correction capability in the decoding, various techniques for the calculation of a likelihood value have been suggested (e.g. refer to patent documents 2 and 3).

Moreover, the data encoded by the LDPC code applied to the communication field is associated with multilevel modulation in most cases, and a noise-prone bit position or the like may vary depending on a modulation method or the like. Thus, there has been suggested a technique of decoding the data more preferably on the basis of the modulation method (e.g. refer to a patent document 4).
Patent document 1: Japanese Patent Application Laid Open No. 2003-198383
Patent document 2: Japanese Patent Application Laid Open No. 2005-302079
Patent document 3: Japanese Patent Application Laid Open No. 2007-272973
Patent document 4: Japanese Patent Application Laid Open No. 2004-64756

### DISCLOSURE OF INVENTION

### Subject to be Solved by the Invention

However, the technique of the decoding based on the modulation method described above is aimed at the modulation method in the communication (i.e. multilevel modulation). Here, in the decoding of the data modulated by a modulation method other than the multilevel modulation, which is often used when recording is performed on a recording medium, a relation between the modulation method in the aforementioned technique and the influence of the noise no longer holds true. Thus, there is such a technical problem that the error correction capability is not likely appropriately improved in the decoding of the data modulated in the modulation method other than the multilevel modulation.

In view of the aforementioned problems, it is therefore an object of the present invention to provide a check matrix generating method, a check matrix, a decoding apparatus and a decoding method in which an error correction capability can be improved in the decoding together with demodulation.

### Means for Solving the Subject

The above object of the present invention can be achieved by a check matrix generating method of generating a check matrix for decoding coded modulation data, which is encoded by a low-density parity check code and which is modulated by converting a-bit data (wherein a is a natural number) to b-bit data (wherein b is a natural number) wherein a is a modulation symbol unit, the method provided with: a check matrix generating process of generating the check matrix by determining each element such that the number of elements of 1 is less than or equal to one, out of a elements corresponding to data of the same modulation symbol in each of rows which constitute the check matrix.

According to the check matrix generating method of the present invention, the check matrix is generated for decoding the coded modulation data, which is encoded by a LDPC code and which is modulated. Here, the modulation is performed by converting a-bit data (wherein a is a natural number) to b-bit data (wherein b is a natural number) wherein a is a modulation symbol unit. Incidentally, the “modulation symbol” indicates the number of bits which is a standard in the modulation, and it has a different value depending on a modulation method. Moreover, for example, it is assumed to include the maximum bit number in a variable RLL (Run-Length Limited) code (the number of bits which is the maximum word length on a conversion table showing a modulation rule) (refer to a patent document 5).
Patent document 5: Japanese Patent Application Laid Open No. Hei 7-240691

The coded modulation data is recorded onto a recording medium or the like after being encoded and modulated, and it is decoded in reproduction. More typically, the coded modulation data is modulated before being decoded. In demodulation, as opposed to the aforementioned modulation, the b-bit data is converted to the a-bit data. In the decoding, information referred to as a message is exchanged on a tanner graph, which is a bipartite graph including a plurality of check nodes and a plurality of variable nodes based on the check matrix. The message is sent along a branch (edge) connecting between the check node and the variable node.

In the present invention, in particular, the check matrix used in the decoding described above is generate such that the number of the elements of 1 is less than or equal to one, out of the a elements corresponding to the data of the same modulation symbol in each of the rows which constitute the check matrix. In other words, two or more “1”s are not included in the elements corresponding to the data of the same modulation symbol. Incidentally, the element “1” herein means the presence of the branch on the tanner graph.

Here, for example, a noise which occurs when the coded modulation data is recorded or reproduced, due to a reduction in SNR (Signal to Noise Ratio) extremely highly likely occurs by the modulation symbol unit. In other words, there is a high possibility that the data has an error in every a bits.

In contrast, if the check matrix is generated as described above, even if there are errors in the a data in the same modulation symbol and a error likelihood values are generated, each of a variable nodes corresponding to this a likelihood values is not connected to the same check node. Thus, of the a error likelihood values, a plurality of likelihood values are not sent to one check node. Therefore, it is possible to reduce a ratio of the error message in one check node and to reduce error probability in the decoding.

As explained above, according to the check matrix generating method of the present invention, it is possible to preferably generate the check matrix on the basis of the modulation method. Therefore, it is possible to improve the error correction capability in the decoding.

In one aspect of the check matrix generating method of the present invention, the check matrix generating method is further provided with a base matrix generating process of generating a base matrix, and the check matrix generating process generates the check matrix by replacing each of the base material by a zero matrix and a cyclic permutation matrix having a size which is an integral multiple of the modulation symbol unit a such that a value of each element of the base matrix corresponds to cyclic shift amount of the cyclic permutation matrix.

According to this aspect, firstly before the check matrix is generated, the base matrix, which is a base for the check matrix, is generated. Then, the check matrix is generated by replacing each element of the base material by the zero matrix and the cyclic permutation matrix. Incidentally, the “cyclic permutation matrix” is a square matrix there is only one “1” in each row and in column, such as a unit matrix, and the “zero matrix” is a square matrix with elements of “0” in which the size (i.e. the number of rows and the number of columns) is the same as that of the cyclic permutation matrix. Each element of the base matrix and the cyclic permutation matrix is replaced such that the value of each element of the base matrix corresponds to the cyclic shift amount of the cyclic permutation matrix. In other words, the check matrix herein is a check matrix corresponding to a so-called QC (Quai Cyclic)-LDPC code. Incidentally, the “cyclic shift amount” is a value indicating how many times the cyclic permutation matrix is cyclic-shifted. For example, if the element of the base material is “1”, it is replaced by a matrix obtained by cyclic-shifting the cyclic permutation matrix once to the right. Moreover, if the element is a negative value and it cannot correspond to the cyclic shift amount, then, it is replaced by the zero matrix.

In this aspect, in particular, the size of the zero matrix and the cyclic permutation matrix to be replaced is the integral multiple of the modulation symbol unit a. Thus, of the a elements corresponding to the data of the same modulation symbol in each of the rows which constitute the check matrix, the number of elements of “1” is less than or equal to one. Therefore, it is possible to improve the error correction capability in the decoding.

In another aspect of the check matrix generating method of the present invention, the check matrix generating method is further provided with a fundamental matrix generating process of generating a fundamental matrix having the same row number and the same column number as those of the check matrix, and the check matrix generating process generates the check matrix by replacing each of columns which constitute the fundamental matrix by each other such that the number of elements of 1 is less than or equal to one, out of a elements corresponding to data of the same modulation symbol in each of rows which constitute the fundamental matrix.

According to this aspect, firstly before the check matrix is generated, the fundamental matrix, which is a base for the check matrix, is generated. Incidentally, the fundamental matrix has the same number of rows and the same number of columns as those of the check matrix and includes elements “0” and “1”. In this fundamental matrix, each row is replaced by each other such that the number of the elements of 1 is less than or equal to one, out of the a elements corresponding to data of the same modulation symbol in each of rows which constitute the fundamental matrix. Thus, of the a elements corresponding to data of the same modulation symbol in each of rows which constitute the check matrix, the number of the elements of “1” is certainly less than or equal to one. Therefore, it is possible to improve the error correction capability in the decoding.

The check matrix generating method in this aspect can be applied to, for example, a check matrix generating method proposed by Gallager (i.e. a method of generating a check matrix corresponding to a Gallager code).

In another aspect of the check matrix generating method of the present invention, the check matrix generating process generates a check matrix corresponding to an Array-LDPC code by arranging cyclic permutation matrices having a size which is an integral multiple of the modulation symbol unit a, on the basis of a predetermined rule.

According to this aspect, the check matrix corresponding to the Array-LDPC code is generated by arranging the plurality of cyclic permutation matrices on the basis of the predetermined rule. Specifically, if the size of the cyclic permutation matrix is p, the cyclic permutation matrices which are not cyclic-shifted are arranged on the p rows from the top of the check matrix. Then, for the next p rows, the cyclic permutation matrix which is not cyclic-shifted is placed on the leftmost side, then, a once-cyclic-shifted cyclic permutation, a twice-cyclic-shifted cyclic permutation matrix, a third-time-cyclic-shifted cyclic permutation matrix, and so on are arranged. Then, for the next p rows, the cyclic permutation matrix which is not cyclic-shifted is placed on the leftmost side, then, a once-cyclic-shifted cyclic permutation matrix, a twice-cyclic-shifted cyclic permutation matrix, a third-time-cyclic-shifted cyclic permutation matrix, and a four-time-cyclic-shifted cyclic permutation matrix and so on are arranged.

In this aspect, in particular, the size (i.e. the number of rows and the number of columns) of the cyclic permutation matrix to be replaced is the integral multiple of the modulation symbol unit a. Thus, of the a elements corresponding to the data of the same modulation symbol in each of the rows which constitute the check matrix, the number of the elements “1” is less than or equal to one. Therefore, it is possible to improve the error correction capability in the decoding.

In another aspect of the check matrix generating method of the present invention, the coded modulation data is interleaved by a function f(x), the check matrix generating method is further provided with a replacing process of replacing, after the check matrix generating process, each of elements which constitute the check matrix, by each other, on the basis of a function f⁻¹(x) which satisfies x=f{f⁻¹(x)}=f⁻¹{f(x)}.

According to this aspect, the coded modulation data is interleaved (i.e. changed in alignment) by the function f(x). Since the coded modulation data is interleaved, it is possible to preferably correct the errors even if the errors occur intensively in a particular portion of the data.

In this aspect, in particular, firstly, of the a elements corresponding to the data of the same modulation symbol in each of the rows which constitute the check matrix, it is generated such that the number of the elements of 1 is less than or equal to one, and then, each of the columns which constitute the check matrix is replaced by each other on the basis of the function f⁻¹(x). The function f⁻¹(x) satisfies x=f{f⁻¹(x)}=f⁻¹(x)}. In other words, the function f⁻¹(x) is a function used when the interleaved data is deinterleaved (returned in alignment).

Thus, even if the data alignment is changed by the aforementioned interleaving, the number of the elements of 1 is less than or equal to one, out of the a elements corresponding to the data of the same modulation symbol in each of the rows which constitute the check matrix. Therefore, it is possible to improve the error correction capability in the decoding.

In another aspect of the check matrix generating method of the present invention, the modulation symbol is a maximum bit number in modulation which uses a variable-length RLL code.

According to this aspect, of the a elements wherein a is the maximum bit number when the variable-length RLL code is use as the modulation rule, it is generate such that the number of the elements of “1” is less than or equal to one. Thus, it is possible to improve the error correction capability when the variable-length RLL code is use as the modulation rule. In other words, it is possible to effectively improve the error correction capability by using that the data highly likely has an error in every a bits wherein a is the maximum bit number.

The above object of the present invention can be also achieved by a check matrix for decoding coded modulation data, which is encoded by a low-density parity check code and which is modulated by converting a-bit data (wherein a is a natural number) to b-bit data (wherein b is a natural number) wherein a is a modulation symbol unit, wherein the check matrix is generated by determining each element such that the number of elements of 1 is less than or equal to one, out of a elements corresponding to data of the same modulation symbol in each of rows which constitute the check matrix.

The check matrix of the present invention is generated by determining each element such that the number of the elements of 1 is less than or equal to one, out of the a elements corresponding to the data of the same modulation symbol in each of the rows which constitute the check matrix. Thus, as in the aforementioned check matrix generating method of the present invention, the ease of occurrence of the error which varies depending on the modulation method is considered. Therefore, it is possible to improve the error correction capability in the decoding.

Incidentally, the check matrix of the present invention can adopt the same various aspects as those of the check matrix generating method of the present invention described above.

The above object of the present invention can be also achieved by a decoding apparatus provided with a decoding device for decoding coded modulation data, which is encoded by a low-density parity check code and which is modulated by converting a-bit data (wherein a is a natural number) to b-bit data (wherein b is a natural number) wherein a is a modulation symbol unit, on the basis of the check matrix of the present invention described above (including its various aspects).

According to the decoding apparatus of the present invention, when the coded modulation data is decoded, the aforementioned check matrix of the present invention is used. Therefore, it is possible to improve the error correction capability in the decoding. Incidentally, if the modulation using the variable RLL code is performed, the modulation symbol unit, a, may be the maximum bit number. Moreover, the decoding apparatus of the present invention may be provided with a demodulating device for demodulation the modulated data, or the like.

The above object of the present invention can be also achieved by a decoding method provided with a decoding process of decoding coded modulation data, which is encoded by a low-density parity check code and which is modulated by converting a-bit data (wherein a is a natural number) to b-bit data (wherein b is a natural number) wherein a is a modulation symbol unit, on the basis of the check matrix of the present invention described above (including its various aspects).

According to the decoding method of the present invention, when the coded modulation data is decoded, the aforementioned check matrix of the present invention is used. Therefore, it is possible to improve the error correction capability in the decoding. Incidentally, if the modulation using the variable RLL code is performed, the modulation symbol unit, a, may be the maximum bit number. Moreover, the decoding apparatus of the present invention may be provided with a demodulating device for demodulation the modulated data, or the like.

The operation and other advantages of the present invention will become more apparent from the embodiments explained below.

### BRIEF DESCRIPTION OF DRAWINGS

FIG. 1 is a block diagram (part 1) showing a flow of data coding and decoding together with an apparatus structure.

FIG. 2 is a conceptual view showing input data before modulation and data after modulation.

FIG. 3 is a flowchart showing a flow of a method of generating a check matrix in a first embodiment.

FIG. 4 is a view showing a base matrix which is a base for the check matrix.

FIG. 5 is a view showing one example of the check matrix including a cyclic permutation matrix.

FIG. 6 is a view (part 1) showing one example of the check matrix generated by the method of generating the check matrix in the first embodiment.

FIG. 7 is a tanner graph corresponding to the check matrix shown in FIG. 6.

FIG. 8 is a view (part 1) showing one example of the check matrix generated by a method of generating a check matrix in a comparative example.

FIG. 9 is a tanner graph corresponding to the check matrix shown in FIG. 8.

FIG. 10 is a graph (part 1) showing a relation between a bit error rate and a signal-to-noise ratio in decoding.

FIG. 11 is a view (part 2) showing one example of the check matrix generated by the method of generating the check matrix in the first embodiment.

FIG. 12 is a tanner graph corresponding to the check matrix shown in FIG. 11.

FIG. 13 is a view (part 2) showing one example of the check matrix generated by the method of generating the check matrix in the comparative example.

FIG. 14 is a tanner graph corresponding to the check matrix shown in FIG. 13.

FIG. 15 is a graph (part 2) showing the relation between the bit error rate and the signal-to-noise ratio in decoding.

FIG. 16 is a flowchart showing a flow of a method of generating a check matrix in a second embodiment.

FIG. 17 is a view showing one block in a fundamental matrix H′.

FIG. 18 is a view showing one example of a check matrix generated by a method of generating a check matrix in a third embodiment.

FIG. 19 is a view showing the cyclic permutation matrix which constitutes the check matrix.

FIG. 20 is a block diagram (part 2) showing a flow of data coding and decoding together with the apparatus structure.

FIG. 21 is a flowchart showing a flow of a method of generating a check matrix in a fourth embodiment.

### DESCRIPTION OF REFERENCE CODES

110 LDPC encoder
120 modulator
130 marker applicator
140 marker detector
150 demodulator
160 LDPC decoder
170 interleaver
180 deinterleaver
200 holographic memory

### BEST MODE FOR CARRYING OUT THE INVENTION

Hereinafter, embodiments of the present invention will be explained with reference to the drawings. The explanation below will be given by exemplifying a case in which coded modulation data is stored in a holographic memory.

### First Embodiment

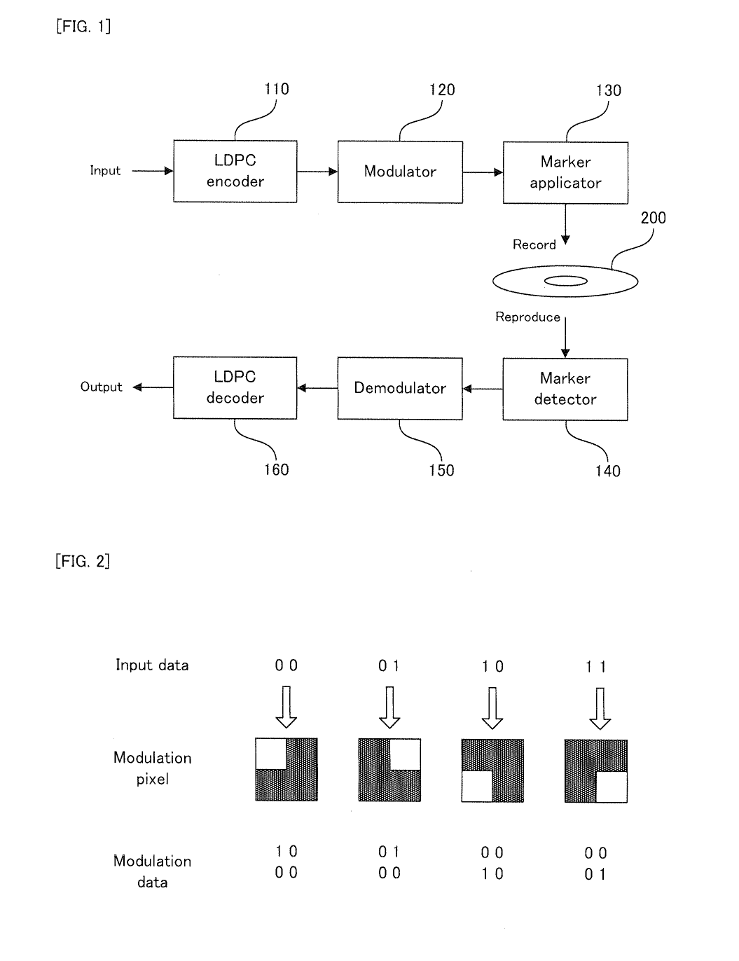

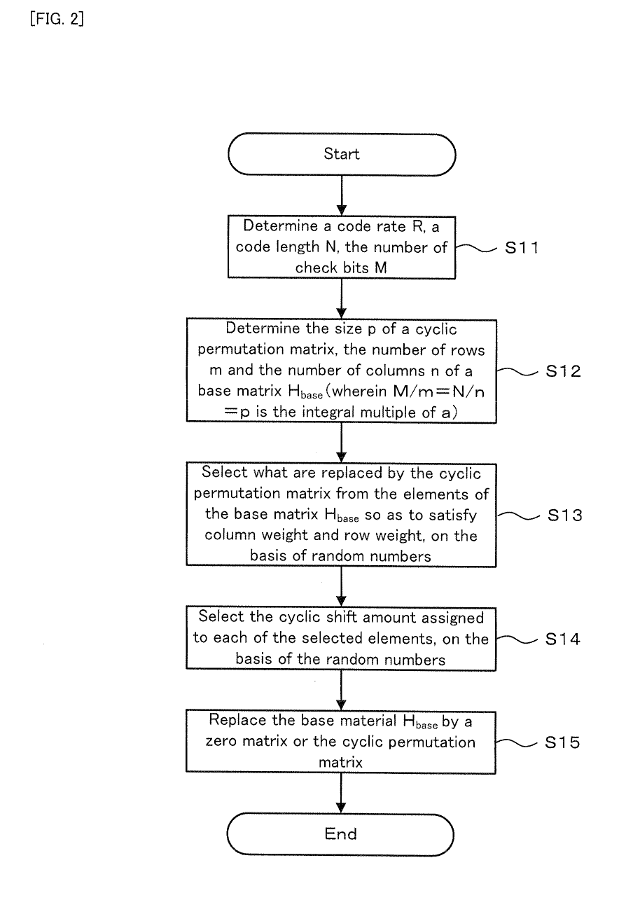

Firstly, the structure of a decoding apparatus in a first embodiment and a flow from data coding to decoding will be explained with reference to FIG. 1 and FIG. 2. FIG. 1 is a block diagram (part 1) showing the flow of data coding and decoding together with the apparatus structure. FIG. 2 is a conceptual view showing input data before modulation and data after modulation.

In FIG. 1, data decoded by the decoding apparatus in the first embodiment is firstly encoded by a LDPC encoder 110. In other words, a LDPC code to which the parity of the LDPC code is applied is generated. Then, the coded data is modulated on a modulator 120. In the modulation, a-bit data is converted to b-bit data, wherein a is a modulation symbol unit.

In FIG. 2, for example, if (2, 4) modulation is performed in which 2-bit data is converted to 4-bit data, the data is converted as shown in FIG. 2. In other words, the 2-bit data is converted to the 4-bit data shown by four pixels.

Back in FIG. 1, a marker for position correction and a sync pattern for synchronization detection and the like in the detection are applied to the modulated data on the marker applicator 130. Then, the data is recorded onto a holographic memory 200.

A reproduction signal reproduced from the holographic memory 200 is converted, for example, by an A/D (Analog to Digital) converter (not illustrated) to a reproduction sample value series. A geometric correction process by the detection of the marker, or a synchronization process by the detection of the sync pattern is performed on the reproduction sample value series on the marker detector 140, by which a modulation sample value series is extracted.

The modulation sample value series is demodulated on a demodulator 150, which is provided with a SISO (Soft-In-Soft-Out) demodulator or the like, and it is outputted as a demodulation sample value series. The SISO demodulator performs maximum-likelihood decoding, for example, by Viterbi decoding, but the output is not binary data like the normal Viterbi decoding, but multilevel data. Incidentally, for example, the SISO demodulator is realized by a decoder which uses a BCJR algorithm.

The LDPC decoder 160 is one example of the “decoding device” of the present invention, and it decodes the inputted demodulation sample value series (i.e. likelihood information) on the basis of a check matrix H for defining the LDPC code. Specifically, on a tanner graph which is a bipartite graph corresponding to the check matrix, iterative decoding is performed by exchanging a message, such as an advance value ratio and an external value. The message is exchanged between a variable node and a check node on the tanner graph via a branch provided in association with the element “1” in the check matrix H.

At this time, a maximum a posteriori probability is obtained, for example, by Sum-Product decoding. Here, if the syndrome calculation of a temporary estimated word generated from a code bit obtained by the Sum-Product decoding is “0”, then, LDPC correction data (binary value) from which the LDPC parity is removed as no error is outputted. On the other hand, if the syndrome calculation is “1”, the iterative decoding is performed until a maximum predetermined number of times set in advance, and the syndrome calculation is performed at each time. If the iterative decoding reaches to the maximum predetermined number, an error process is performed and then is shifted to a subsequent process.

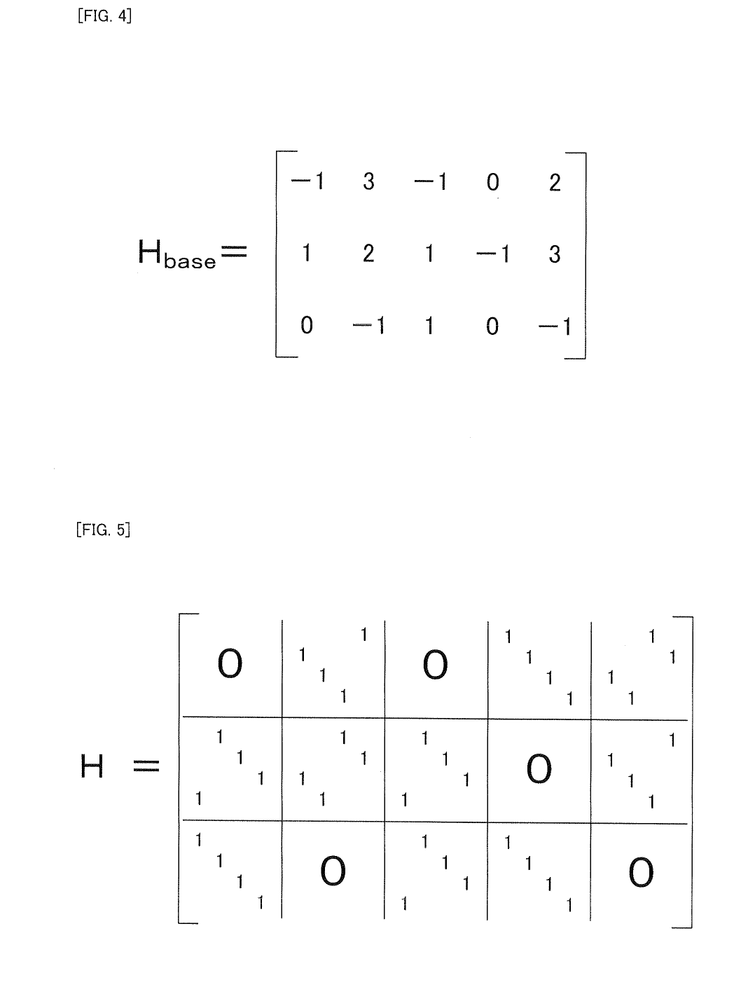

Next, a method of generating the check matrix used on the decoding apparatus in the first embodiment will be explained with reference to FIG. 3 to FIG. 5. FIG. 3 is a flowchart showing a flow of the method of generating the check matrix in the first embodiment. FIG. 4 is a view showing a base matrix which is a base for the check matrix. FIG. 5 is a view showing one example of the check matrix including a cyclic permutation matrix. Incidentally, hereinafter, an explanation will be given on a case where a check matrix corresponding to a QC-LDPC code is generated.

In FIG. 3, in the generation of the check matrix in the first embodiment, firstly, a code ratio R, a code length N and the number of check bits M (i.e. parity bits) are determined (step S11). Then, the number of rows m and the number of columns n in a base matrix H_{base} and the size p (i.e. the number of rows and the number of columns) of the cyclic permutation matrix by which each element of the H_{base} is replaced are determined (step S12). Here, in particular, if the modulation on the modulator 120 is (a, b) modulation, M/m=N/n=p is determined to be the integral multiple of a. By this, of a elements corresponding to the data of the same modulation symbol in each of the rows which constitute the generated check matrix H, the number of elements “1” is certainly less than or equal to 1. Incidentally, “a” herein may be the maximum bit number in a variable-length RLL code.

Then, what are replaced by the cyclic permutation matrix are selected from the elements of the base matrix H_{base} satisfying column weight (the number of “1”s in each of the columns which constitute the check matrix) and row weight (the number of “1”s in each of the rows which constitute the check matrix) on the basis of random numbers (step S13), and the cyclic shift amount of “p-1” is selected from “0” assigned to each of the selected elements, on the basis of the random numbers (step S14). At this time, the cyclic shift amount is selected such that a loop is not “4” (i.e. such that it does not return to an original node after moving on the branches four times on the tanner graph).

At last, the check matrix H is generated by replacing the elements of the base matrix H_{base} by a zero matrix and the cyclic permutation matrix (step S15).

As shown in FIG. 4, for example, if the base matrix H_{base} with 3 rows and 5 columns is generated, the element “0” of the base matrix H_{base} is replaced by a unit matrix, and the element “1” is replaced by a matrix obtained by cyclic-shifting the unit matrix once to the right. Moreover, an element “2” is replaced by a matrix obtained by cyclic-shifting the unit matrix twice to the right, and an element “3” is replaced by a matrix obtained by cyclic-shifting the unit matrix three times to the right. An element “−1” is replaced by the zero matrix.

As shown in FIG. 5, in H_{base} shown in FIG. 4, each element is replaced by the zero matrix and the cyclic permutation matrix with 4 rows and 4 columns (i.e. with a size p of 4). Incidentally, in FIG. 5, the zero matrices are shown by “0”, and the elements “0” are omitted and only the elements “1” are shown in the other cyclic permutation matrices. If the modulation on the modulator 120 is (2, 4) modulation, then, the size of the zero matrix and the cyclic permutation matrix, p=4, is the integral multiple of 2 which is a modulation symbol unit. In this case, as can be seen from the check matrix H shown in FIG. 5, a plurality of “1”s are not included in the elements corresponding to the data of the same modulation symbol in each row (i.e. two elements adjacent to each other).

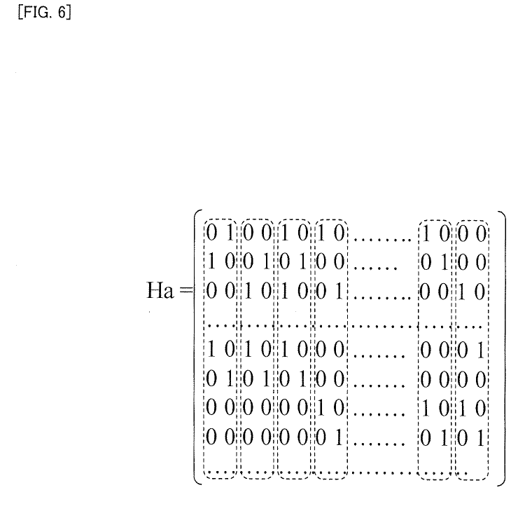

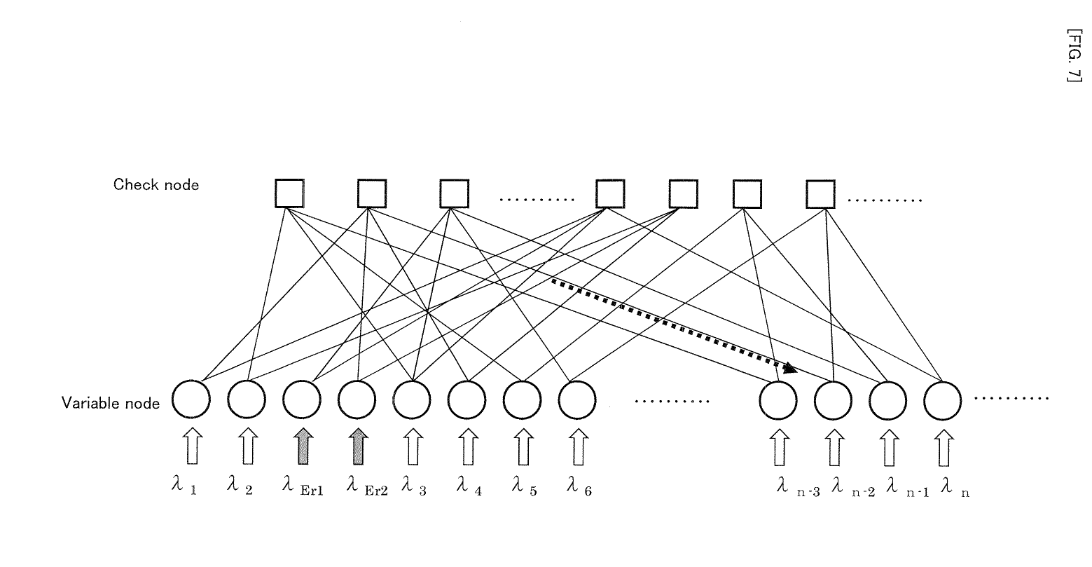

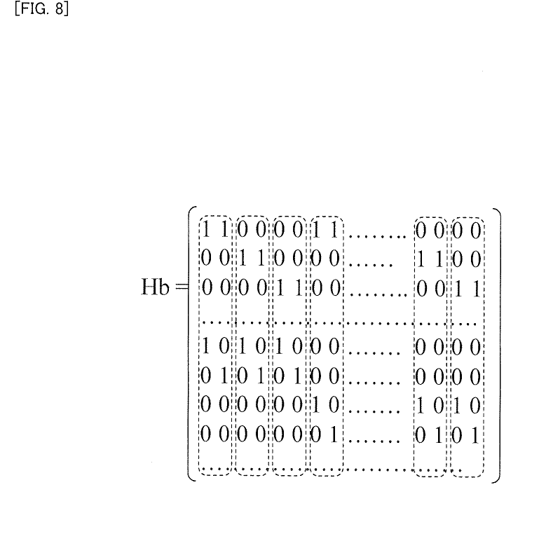

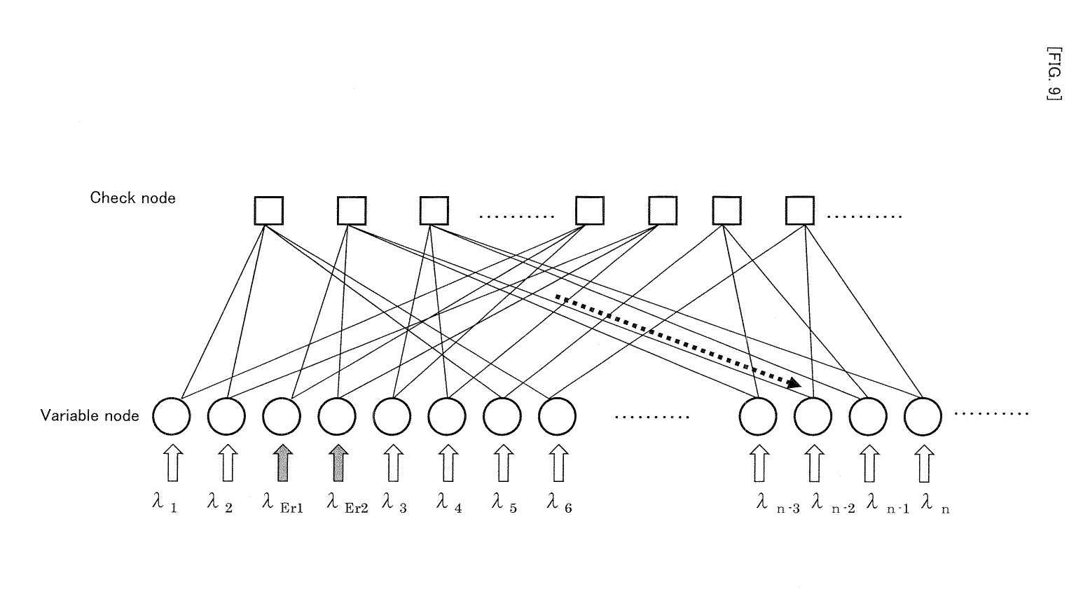

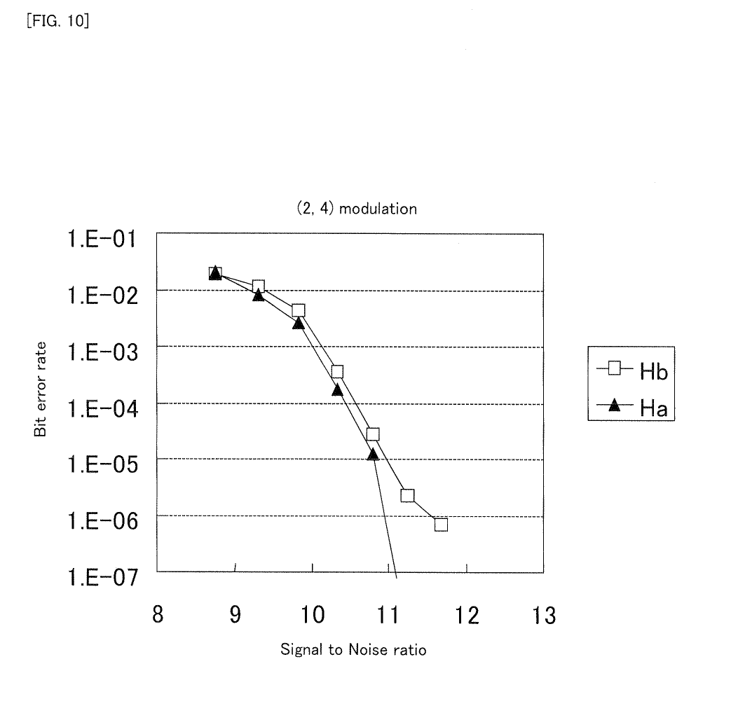

Next, an effect by using the aforementioned will be explained with reference to FIG. 6 to FIG. 10. FIG. 6 is a view (part 1) showing one example of the check matrix generated by the method of generating the check matrix in the first embodiment. FIG. 7 is a tanner graph corresponding to the check matrix shown in FIG. 6. FIG. 8 is a view (part 1) showing one example of the check matrix generated by a method of generating a check matrix in a comparative example. FIG. 9 is a tanner graph corresponding to the check matrix shown in FIG. 8. FIG. 10 is a graph (part 1) showing a relation between a bit error rate and a signal-to-noise ratio in decoding. Incidentally, hereinafter, the explanation will be given by exemplifying a case where the modulator 120 (refer to FIG. 1) performs (2, 4) modulation.

In FIG. 6 and FIG. 7, for example, it is assumed that a check matrix Ha shown in FIG. 6 is generated by the method of generating the check matrix in the first embodiment described above. Then, the tanner graph corresponding to the check matrix Ha is as shown in FIG. 7. Incidentally, the check node on the tanner graph corresponds to each row of the check matrix Ha, and the variable node corresponds to each column of the check matrix Ha. Moreover, the branch exists only in a portion with an element of “1”.

In the check matrix Ha shown in FIG. 6, a plurality of “1”s are not included in the elements corresponding to the data of the same modulation symbol in each row. Specifically, of the elements surrounded in a dashed line in FIG. 6, a plurality of “1”s are not included in the same row. Thus, on the tanner graph shown in FIG. 7, edges are not connected to the same check node from the variable nodes corresponding to the data of the same modulation symbol.

For example, it is assumed that there is an error in one modulation symbol in the data to be decoded and that two likelihood values (λ_{Er1}, λ_{Er2}) generated from the error modulation symbol are inputted. On the other hand, as described above in the first embodiment, the edges are not connected to the same check node from the variable nodes corresponding to the data of the same modulation symbol. Thus, the two likelihood values (λ_{Er1}, λ_{Er2}) generated from the error modulation symbol are not sent to the same check node. Specifically, in a message exchanged by the edge shown by the arrow in FIG. 7, likelihood values (λ₁, λ₄, λ_{Er2}) are included, and there is only one error likelihood value. In the other edges, in the same manner, there is at most one error likelihood value included.

In FIG. 8 and FIG. 9, for example, it is assumed that a check matrix Hb shown in FIG. 8 is generated by a method of generating a check matrix other than the check matrix in the first embodiment described above. Then, the tanner graph corresponding to the check matrix Hb is as shown in FIG. 9. In the check matrix Hb, a plurality of “1”s are included in the elements corresponding to the data of the same modulation symbol in each row. Thus, on the tanner graph shown in FIG. 9, as opposed to the tanner graph shown in FIG. 7, the edges are connected to the same check node from the variable nodes corresponding to the data of the same modulation symbol in some cases.

Here, as in the aforementioned case, it is assumed that there is an error in one modulation symbol in the data to be decoded and that the two likelihood values (λ_{Er1}, λ_{Er2}) generated from the error modulation symbol are inputted. Here on the tanner graph in the comparative example, as described above, the edges are connected to the same check node from the variable nodes corresponding to the data of the same modulation symbol in some cases. Thus, the two likelihood values (λ_{Er1}, λ_{Er2}) generated from the error modulation symbol are sent to the same check node in some cases. Specifically, in a message exchanged by the edge shown by the arrow in FIG. 9, likelihood values (λₙ₋₃, λ_{Er1}, λ_{Er2}) are included, and both the two error likelihood values are included. In the other edges, in the same manner, the two error likelihood values are included in some cases.

In FIG. 10, if the decoding is performed by using the check matrix generated by the method of generating the check matrix in the first embodiment, the weight of the error message can be reduced. According to the study of the inventors of this application, as shown in the graph, if the signal to noise ratio is the same, the bit error rate in the decoding by the check matrix Ha is always smaller than the bit error rate in the decoding with the check matrix Hb.

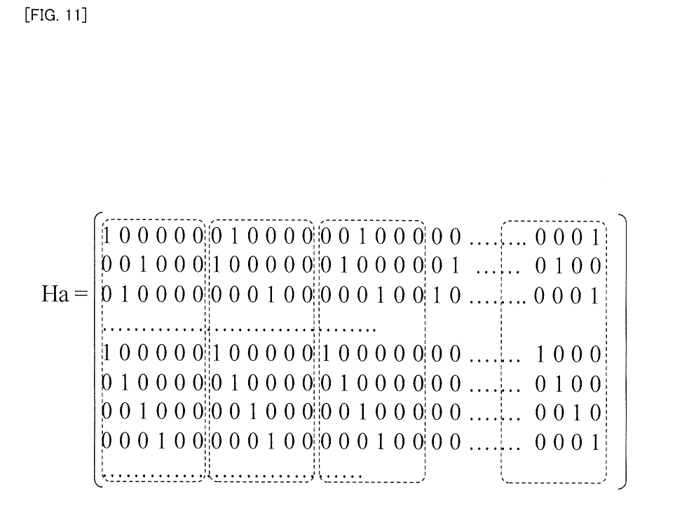

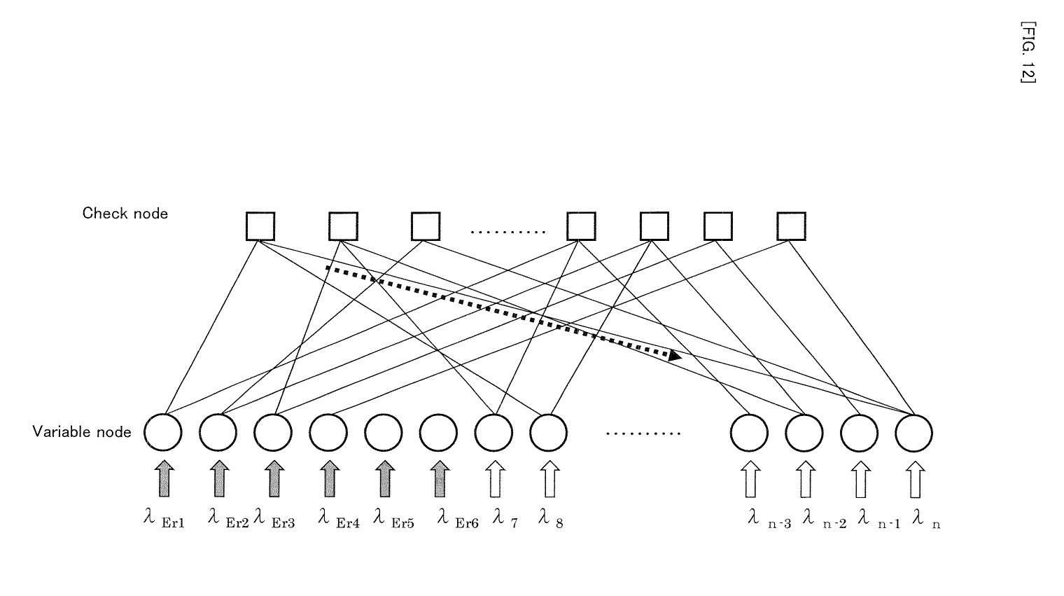

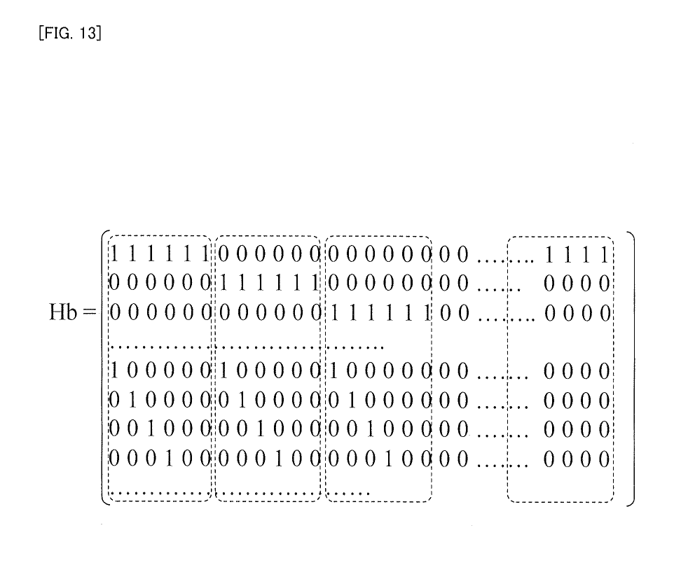

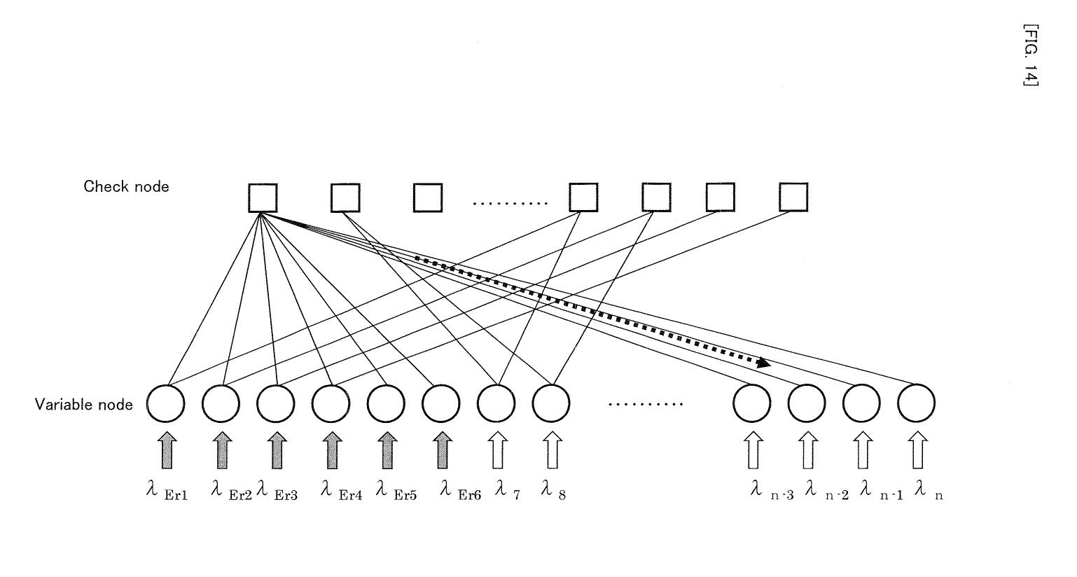

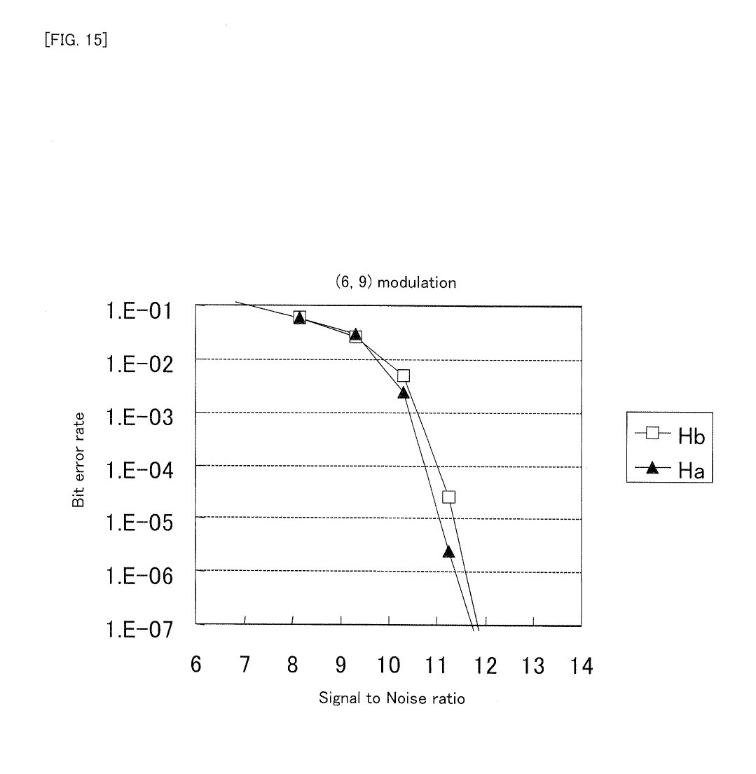

Next, an explanation will be given on a case where (6, 9) modulation is performed, with reference to FIG. 11 to FIG. 15. FIG. 11 is a view (part 2) showing one example of the check matrix generated by the method of generating the check matrix in the first embodiment. FIG. 12 is a tanner graph corresponding to the check matrix shown in FIG. 11. FIG. 13 is a view (part 2) showing one example of the check matrix generated by the method of generating the check matrix in the comparative example. FIG. 14 is a tanner graph corresponding to the check matrix shown in FIG. 13. FIG. 15 is a graph (part 2) showing the relation between the bit error rate and the signal-to-noise ratio in decoding.

In FIG. 11 and FIG. 12, for example, it is assumed that a check matrix Ha shown in FIG. 11 is generated by the method of generating the check matrix in the first embodiment described above. Then, the tanner graph corresponding to the check matrix Ha is as shown in FIG. 12. In the check matrix Ha shown in FIG. 11, a plurality of “1”s are not included in the elements corresponding to the data of the same modulation symbol in each row. Specifically, of the elements surrounded in a dashed line in FIG. 11, a plurality of “1”s are not included in the same row. Thus, on the tanner graph shown in FIG. 12, the edges are not connected to the same check node from the variable nodes corresponding to the data of the same modulation symbol.

For example, it is assumed that there is an error in one modulation symbol in the data to be decoded and that six likelihood values (λ_{Er1} to λ_{Er6}) generated from the error modulation symbol are inputted. On the other hand, as described above in the first embodiment, the edges are not connected to the same check node from the variable nodes corresponding to the data of the same modulation symbol. Thus, the six likelihood values (λ_{Er1} to λ_{Er6}) generated from the error modulation symbol are not sent to the same check node. Specifically, in a message exchanged by the edge shown by the arrow in FIG. 12, likelihood values (λ₇, λ_{Er1}) are included, and there is only one error likelihood value. In the other edges, in the same manner, there is at most one error likelihood value included.

In FIG. 13 and FIG. 14, for example, it is assumed that a check matrix Hb shown in FIG. 13 is generated by a method of generating a check matrix other than the check matrix in the first embodiment described above. Then, the tanner graph corresponding to the check matrix Hb is as shown in FIG. 14. In the check matrix Hb, a plurality of “1”s are included in the elements corresponding to the data of the same modulation symbol in each row. Thus, on the tanner graph shown in FIG. 14, as opposed to the tanner graph shown in FIG. 12, the edges are connected to the same check node from the variable nodes corresponding to the data of the same modulation symbol in some cases.

Here, as in the aforementioned case, it is assumed that there is an error in one modulation symbol in the data to be decoded and that the six likelihood values (λ_{Er1} to λ_{Er6}) generated from the error modulation symbol are inputted. Here on the tanner graph in the comparative example, as described above, the edges are connected to the same check node from the variable nodes corresponding to the data of the same modulation symbol in some cases. Thus, the six likelihood values (λ_{Er1} to λ_{Er6}) generated from the error modulation symbol are sent to the same check node in some cases. Specifically, in a message exchanged by the edge shown by the arrow in FIG. 14, all the likelihood values (λ_{Er1} to λ_{Er6}) are included. In the other edges, in the same manner, two or more error likelihood values are included in some cases.

In FIG. 15, even in the case of (6, 9) modulation, as in the case of (2, 4) modulation, if the decoding is performed by using the check matrix generated by the method of generating the check matrix in the first embodiment, the weight of the error message can be reduced. According to the study of the inventors of this application, as shown in the graph, if the signal to noise ratio is the same, the bit error rate in the decoding by the check matrix Ha is always smaller than the bit error rate in the decoding with the check matrix Hb.

As explained above, according to the decoding apparatus in the first embodiment, the check matrix is preferably generated on the basis of the modulation method, so that it is possible to improve the error correction capability.

### Second Embodiment

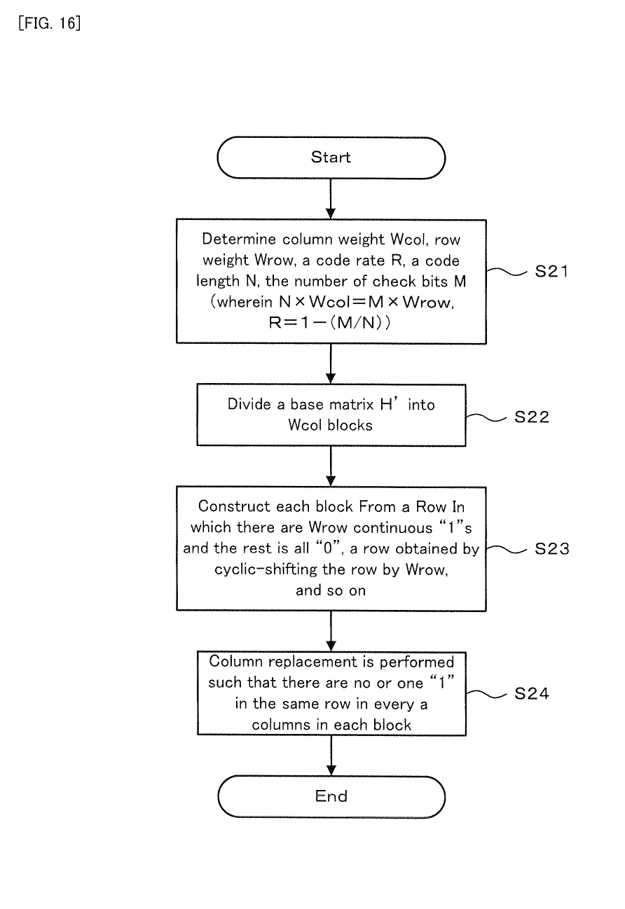

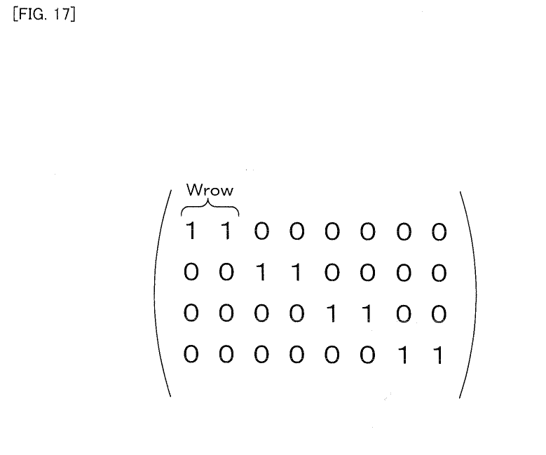

Next, a decoding apparatus in a second embodiment will be explained with reference to FIG. 16 and FIG. 17. FIG. 16 is a flowchart showing a flow of a method of generating a check matrix in the second embodiment. FIG. 17 is a view showing one block in a fundamental matrix H′. Incidentally, the second embodiment is different from the aforementioned first embodiment in a method of generating a check matrix used in the decoding, and they are substantially the same in the apparatus structure, the decoding method, and the like. Thus, here, the different portion from the first embodiment will be explained in detail, and the explanation of the overlap portion will be omitted, as occasion demands.

In FIG. 16, in the decoding apparatus in the second embodiment, a check matrix corresponding to a Gallager code is used. In the generation of a check matrix H, firstly, column weight W_{col}, row weight W_{row}, a code ratio R, a code length N and the number of check bits M are determined (step S21). Here, N×W_{col}=M×W_{row}, and R=1/(M/N). Then, a fundamental matrix H′ having the same size of the check matrix H is divided into W_{col} blocks (step S22).

As shown in FIG. 17, after the fundamental matrix H′ is divided into the blocks, each block is constructed such that it is composed of a first row in which there are W_{row} continuous “1”s and the rest is all “0”, a second row obtained by cyclic-shifting the first row by W_{row}, a third row obtained by cyclic-shifting the second row by W_{row}, and so on (step S23).

Back in FIG. 16, at last, column replacement is performed on the fundamental matrix H′ such that a plurality of “1”s are not included in the elements corresponding to the data of the same modulation symbol in each row (step S24). By this, as in the aforementioned first embodiment, it is possible to generate the check matrix H in which a plurality of “1”s are not included in the elements corresponding to the data of the same modulation symbol in each row. Thus, in the decoding which uses the check matrix H generated by the method of generating the check matrix in the second embodiment, the error rate can be reduced.

As explained above, according to the decoding apparatus in the second embodiment, as in the aforementioned first embodiment, the check matrix is preferably generated on the basis of the modulation method, so that it is possible to improve the error correction capability.

### Third Embodiment

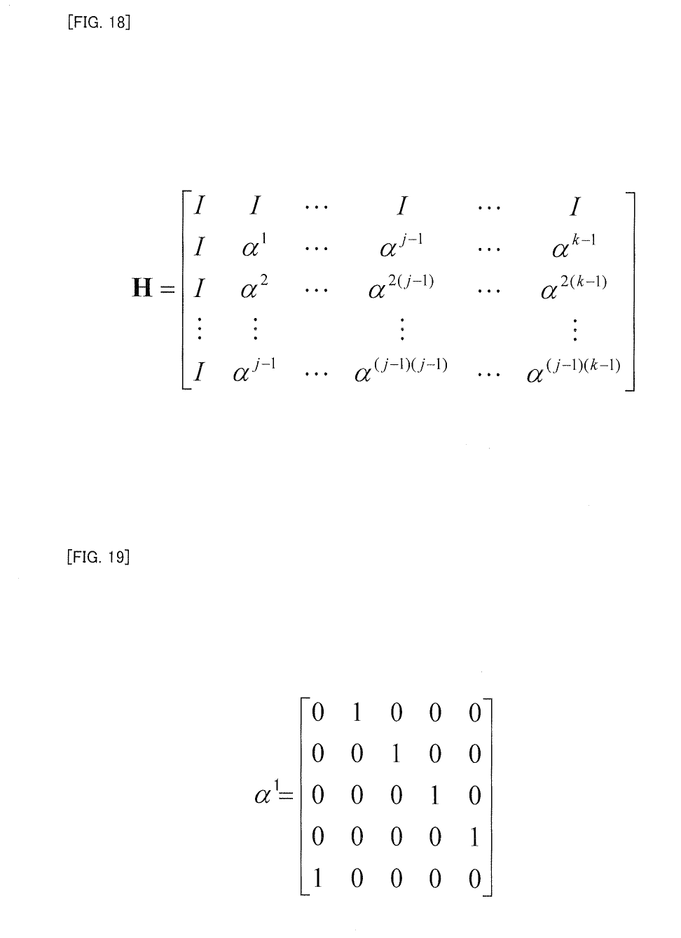

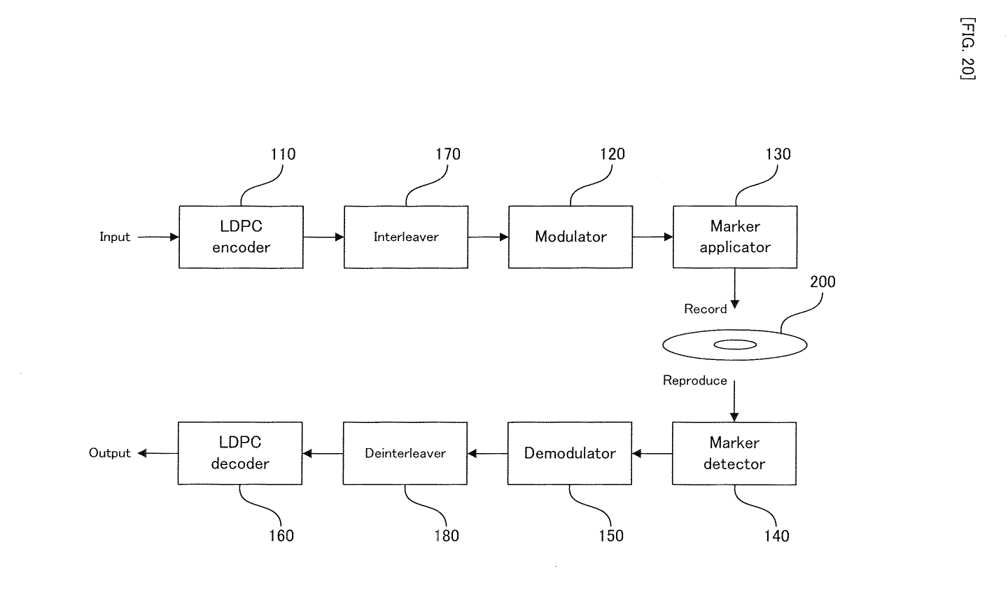

Next, a decoding apparatus in a third embodiment will be explained with reference to FIG. 18 and FIG. 19. FIG. 18 is a view showing one example of a check matrix generated by a method of generating a check matrix in the third embodiment. FIG. 19 is a view showing the cyclic permutation matrix which constitutes the check matrix. Incidentally, the third embodiment is different from the aforementioned first and second embodiments in a method of generating a check matrix used in the decoding, and they are substantially the same in the apparatus structure, the decoding method, and the like. Thus, here, the different portion from the first embodiment will be explained in detail, and the explanation of the overlap portion will be omitted, as occasion demands.

In FIG. 18 and FIG. 19, in the decoding apparatus in the third embodiment, a check matrix corresponding to an Array-LDPC code is used. In a check matrix H corresponding to the Array-LDPC code, an unit matrix I and α^{x}, which is the cyclic permutation matrix of the unit matrix I, are arranged as shown in FIG. 18. Incidentally, the index x of the cyclic permutation matrix α^{x} denotes the cyclic shift amount. For example, as shown in FIG. 19, α¹ means that the unit matrix is cyclic-shifted once to the right. Moreover, the index j in FIG. 18 denotes the column weight, and k denotes the row weight.

Here, the size of the unit matrix I and the cyclic permutation matrix α^{x} is the integral multiple of a, which is a modulation symbol unit. Thus, as in the aforementioned first embodiment, it can be set such that a plurality of “1”s are not included in the elements corresponding to the data of the same modulation symbol in each row. Thus, in the decoding which uses the check matrix H generated by the method of generating the check matrix in the third embodiment, the error rate can be reduced.

As explained above, according to the decoding apparatus in the third embodiment, as in the aforementioned first and second embodiments, the check matrix is preferably generated on the basis of the modulation method, so that it is possible to improve the error correction capability.

### Fourth Embodiment

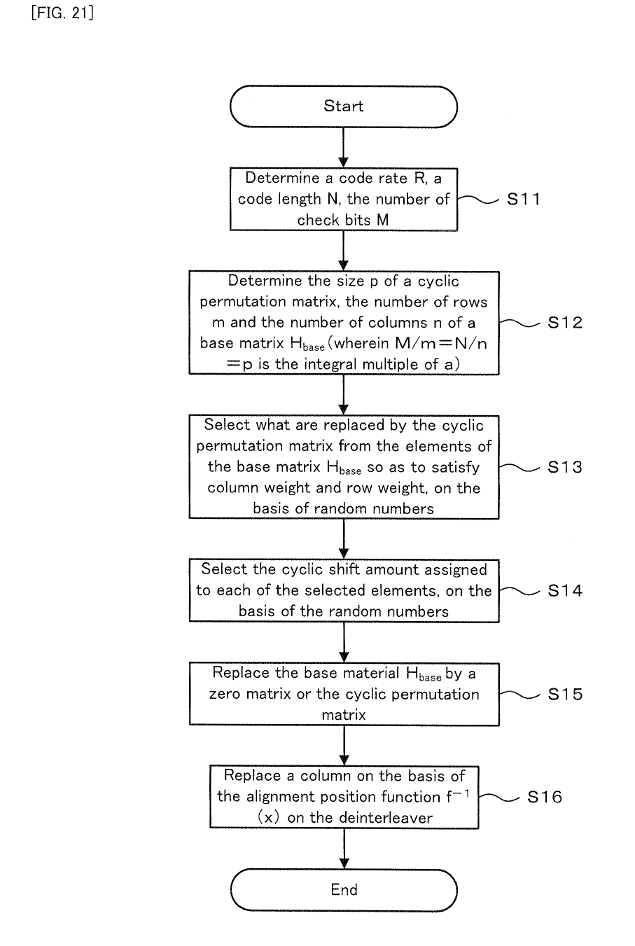

Next, a decoding apparatus in a fourth embodiment will be explained with reference to FIG. 20 and FIG. 21. FIG. 20 is a block diagram (part 2) showing a flow of data coding and decoding together with the apparatus structure. FIG. 21 is a flowchart showing a flow of a method of generating a check matrix in a fourth embodiment. Incidentally, the fourth embodiment is different from the aforementioned embodiments in a method of generating a check matrix used in the decoding, and they are substantially the same in the apparatus structure, the decoding method, and the like. Thus, here, the different portion from the first embodiment will be explained in detail, and the explanation of the overlap portion will be omitted, as occasion demands. Moreover, in FIG. 20 and FIG. 21, the same constituents as those in the first embodiment shown in FIG. 1 and FIG. 3 will carry the same reference numerals.

In FIG. 20, in recording, data decoded by the decoding apparatus in the fourth embodiment is encoded by a LDPC encoder 110 and then is interleaved by an interleaver 170. Specifically, the interleaver 170 rearranges the inputted data alignment on the basis of an alignment position function f(x). Then, in reproduction, the data is demodulated by a demodulator 150 and then is deinterleaved by a deinterleaver 180. Specifically, the deinterleaver 180 rearranges the inputted data alignment on the basis of an alignment position function f⁻¹(x). Incidentally, the function f(x) and the function f⁻¹(x) satisfy x=f{f⁻¹(x)}=f⁻¹{f(x)}.

In FIG. 21, in the method of generating the check matrix in the fourth embodiment, as in the first embodiment, the processes from the step S11 to the step S15 are performed to generate the check matrix H, and then, each column is replaced on the basis of the alignment position function f⁻¹(x) on the deinterleaver 180 (step S16). By this, even if the data is interleaved and recorded, the error rate can be preferably reduced in the decoding. In other words, even if the data is rearranged, the appropriate check matrix H can be generated if how the data is rearranged is known.

As explained above, according to the decoding apparatus in the fourth embodiment, as in the aforementioned first to third embodiments, the check matrix is preferably generated on the basis of the modulation method, so that it is possible to improve the error correction capability.

The present invention is not limited to the aforementioned example, but various changes may be made, if desired, without departing from the essence or spirit of the invention which can be read from the claims and the entire specification. A check matrix generating method, a check matrix, and a decoding apparatus and method, which involve such changes, are also intended to be within the technical scope of the present invention.

### INDUSTRIAL APPLICABILITY

The check matrix generating method, the check matrix, the decoding apparatus and the decoding method of the present invention can be applied to recording and reproduction on a recording medium, such as a next-generation optical disc, a holographic memory, a ferroelectric probe memory, and a HDD (Hard Disc Drive). Moreover, they can be also applied to fields where the LDPC and BCH are standardized, such as communications and broadcasting.

1. A check matrix generating method of generating a check matrix for decoding coded modulation data, which is encoded by a low-density parity check code and which is modulated by converting a-bit data (wherein a is a natural number) to b-bit data (wherein b is a natural number) wherein a is a modulation symbol unit, said method comprising:
a check matrix generating process of generating the check matrix by determining each element such that the number of elements of 1 is less than or equal to one, out of a elements corresponding to data of the same modulation symbol in each of rows which constitute the check matrix.

2. The check matrix generating method according to claim 1, wherein
said check matrix generating method further comprises a base matrix generating process of generating a base matrix, and
said check matrix generating process generates the check matrix by replacing each element of the base material by a zero matrix and a cyclic permutation matrix having a size which is an integral multiple of the modulation symbol unit a such that a value of each element of the base matrix corresponds to cyclic shift amount of the cyclic permutation matrix.

3. The check matrix generating method according to claim 1, wherein
said check matrix generating method further comprises a fundamental matrix generating process of generating a fundamental matrix having the same row number and the same column number as those of the check matrix, and
said check matrix generating process generates the check matrix by replacing each of columns which constitute the fundamental matrix by each other such that the number of elements of 1 is less than or equal to one, out of a elements corresponding to data of the same modulation symbol in each of rows which constitute the fundamental matrix.

4. The check matrix generating method according to claim 1, wherein said check matrix generating process generates a check matrix corresponding to an Array-LDPC code by arranging cyclic permutation matrices having a size which is an integral multiple of the modulation symbol unit a, on the basis of a predetermined rule.

5. The check matrix generating method according to claim 1, wherein
the coded modulation data is interleaved by a function f(x),
said check matrix generating method further comprises a replacing process of replacing, after said check matrix generating process, each of elements which constitute the check matrix, by each other, on the basis of a function f⁻¹(x) which satisfies x=f{f⁻¹(x)}=f⁻¹{f(x)}.

6. The check matrix generating method according to claim 1, wherein the modulation symbol is a maximum bit number in modulation which uses a variable-length RLL code.

7. A check matrix for decoding coded modulation data, which is encoded by a low-density parity check code and which is modulated by converting a-bit data (wherein a is a natural number) to b-bit data (wherein b is a natural number) wherein a is a modulation symbol unit, wherein
the check matrix is generated by determining each element such that the number of elements of 1 is less than or equal to one, out of a elements corresponding to data of the same modulation symbol in each of rows which constitute the check matrix.

8. A decoding apparatus comprising a decoding device for decoding coded modulation data, which is encoded by a low-density parity check code and which is modulated by converting a-bit data (wherein a is a natural number) to b-bit data (wherein b is a natural number) wherein a is a modulation symbol unit, on the basis of the check matrix described in claim 6.

9. A decoding method comprising a decoding process of decoding coded modulation data, which is encoded by a low-density parity check code and which is modulated by converting a-bit data (wherein a is a natural number) to b-bit data (wherein b is a natural number) wherein a is a modulation symbol unit, on the basis of the check matrix described in claim 6.
